(19) United States
(12) Patent Application Publication
(10) Pub. No.: US 2004/0063318 A1
(43) Pub. Date: Apr. 1, 2004

(54) Method of selectively removing metal residues from a dielectric layer by chemical mechanical polishing

(76) Inventors: Rene Kai Nagel, Dresden (DE); Gerd Franz Christian Marxsen, Radebeul (DE); Uwe Gunter Stoeckgen, Dresden (DE)

Correspondence Address: J. Mike Amerson, Williams, Morgan & Amerson, P.C., Suite 1100, 10333 Richmond, Houston, TX, 77042, US

(21) Appl. No.: 10/421,136

(22) Filed: Apr. 23, 2003

(30) Foreign Application Priority Data
Sep. 30, 2002 (DE) 102 45 610.0

(51) Int. Cl. H01L 21/302; H01L 21/461

(52) U.S. Cl. 438/689; 438/692

(57) ABSTRACT

A method is disclosed that provides reliable removal of residues after chemical mechanical polishing of a damascene semiconductor structure so that the residues may be reliably removed without unduly affecting copper trenches and vias. To this end, the relative speed and/or the pressure applied to the substrate is increased and decreased, respectively, to operate the CMP apparatus in a regime with a significantly lowered removal rate while, at the same time, the hydrodynamic lubrication is avoided. Therefore, process time is increased and allows enhanced controllability of the process. Additionally, an improved selectivity of the removal rate of already cleared portions and of portions having residues formed thereon is remarkably improved.

### BACKGROUND OF THE INVENTION

1. Field of the Invention

The present invention generally relates to the field of fabricating integrated circuits, and, more particularly, to the planarization of a metallization layer and/or the removal of excess metal from a dielectric layer.

2. Description of the Related Art

In manufacturing microstructures, such as integrated circuits, various material layers are deposited on a substrate and are patterned by known photolithography and etching processes, and the like, to provide a huge number of individual features such as circuit elements in the form of transistors, capacitors, resistors and the like. Due to the ever-decreasing feature sizes of the individual structure elements, sophisticated photolithography and etch techniques have been developed that allow the resolution of critical dimensions, i.e., of minimum feature sizes, well beyond the wavelength of the radiation used for transferring images from a reticle to a mask layer that is used in subsequent etching processes. Since these sophisticated imaging techniques are quite sensitive to any underlying material layers and to the surface topography, it is frequently necessary to planarize the substrate so as to provide a substantially planar surface for the application of further material layers to be patterned. This is especially true for so-called metallization layers required in integrated circuits to electrically connect the individual circuit elements. Depending on the feature sizes of the circuit elements and the number thereof, a plurality of metallization layers, stacked on top of each other and electrically connected by so-called vias, are typically required for providing for the complex functionality of modern integrated circuits.

It has, therefore, become standard practice in forming stacked metallization layers to planarize the substrate surface prior to forming a subsequent metallization layer. Chemical mechanical polishing (CMP) has proved to be a viable process technique for this purpose. In chemically mechanically polishing a substrate, in addition to the mechanical removal of the material, a slurry is supplied, typically containing one or more chemical reagents that react with the material or materials on the surface, wherein the reaction products may then be more efficiently removed by the mechanical polishing process. In addition to the appropriate selection of the slurry composition, the relative motion between the substrate and a polishing pad, as well as the force with which the substrate is pressed against the polishing pad, are controlled to obtain the desired removal rate.

Recently, chemical mechanical polishing has increasingly gained in importance as aluminum is continuously replaced with copper in high-end integrated circuits exhibiting feature sizes in the deep sub-micron regime. Although copper exhibits superior characteristics compared to aluminum in terms of conductivity and resistance against electromigration, many problems are involved in processing copper in a semiconductor facility, one of which resides in the fact that copper may not be very efficiently deposited in large amounts with well-established deposition techniques, such as chemical vapor deposition and sputter deposition. Moreover, copper may not be efficiently patterned by conventional anisotropic etch techniques. Therefore, instead of applying copper as a blanket layer and patterning metal lines, the so-called damascene method has become a standard process technique in forming metallization layers comprised of copper.

In the damascene technique, trenches and vias are formed in a dielectric layer and the metal is subsequently filled into the trenches and vias, wherein a certain amount of over-filling has to be provided so as to reliably fill the trenches and vias. Prior to depositing the copper, usually by performing a plating process, such as electroplating or electroless plating, a barrier layer is formed in the trench to minimize out-diffusion of copper into the adjacent dielectric. Thereafter, a thin copper seed layer is usually applied using sputter deposition techniques to promote the subsequent plating process of the bulk copper material. After the deposition of the bulk copper, the excess metal, including the thin barrier layer and the seed layer, has to be reliably removed in order to obtain copper trenches and vias that are electrically insulated from each other. The excess material is removed by chemical mechanical polishing, requiring an operation mode for removing the bulk copper in a first polishing period and the removing of copper, the barrier material and to a certain amount the dielectric during a subsequent phase of the polishing process. The polishing process may, therefore, be carried out in at least two steps, possibly requiring a different chemistry in the slurries, as well as different parameter settings for the speed of the relative motion and/or the down force applied to the substrate during these different polishing steps.

Typically, abrasives are added to the slurry for the first step of the CMP process so as to obtain a desired high removal rate for the bulk copper, whereas, in the subsequent step, the removal is more complex, as usually two or more materials have to be polished at the same time, i.e., copper, the barrier material and the dielectric. In many cases, the dielectric may be silicon dioxide and this dielectric, and typically the barrier material, are significantly harder than the copper so that copper is removed more rapidly than the other materials. Moreover, a certain amount of “overpolish” has to be applied in an attempt to remove substantially all of the conductive material on surface portions of the dielectric material to minimize leakage currents or shorts between adjacent copper lines. Completely removing the conductive material from a substrate having a diameter of 200 mm or in future device generations of 300 mm is, however, a challenging task and usually leads to a certain amount of dishing and erosion of the metallization structures and to metal residues, as will be shown in FIGS. 1a-2b.

FIG. 1a schematically shows a cross-sectional view of a semiconductor structure 100 including a substrate 101 with a dielectric layer 102 formed thereon. The substrate 101 may include circuit elements, such as transistors, resistors and the like, which are, for convenience, not shown in FIG. 1a. Trenches 103 and 105 and a via 104 are formed in the dielectric layer 102 and the surfaces thereof, as well as the surface of the dielectric layer 102, are covered by a barrier layer 106. A copper layer 107 is formed over the structure 100 with a thickness that reliably fills the trenches 105 and 103.

The semiconductor structure 100 as shown in FIG. 1a may be formed in accordance with well-known patterning and deposition techniques as already briefly described above, and, therefore, a detailed description will be omitted. The semiconductor structure 100 will then be subjected to a chemical mechanical polishing process, possibly including several individual polish steps to remove the excess copper of the layer 107 and substantially remove the barrier layer 106.

FIG. 1b schematically shows the semiconductor structure 100 after completion of the CMP process. The semiconductor structure 100 comprises large surface portions 110 that are substantially completely free of conductive material, such as copper and barrier material, whereas tiny amounts of residual metal 109 may remain on the dielectric layer 102. These tiny amounts of residual metal 109 may cause leakage currents or even shorts between adjacent trenches 105. In some cases, a certain degree of dishing 108 may be observed, possibly rendering the trench 103 unreliable due to the reduced cross-sectional area that may lead to increased current densities during operation. Since especially the residues 109 may unacceptably increase the risk for reduced performance or even total device failure, the semiconductor structure 100 typically has to be reworked so as to substantially completely remove the residues 109.

As is evident from FIG. 1b, however, clearing the surface portions between the trenches 105 to remove the residues 109 may entail a further damage of other substrate areas, such as the trench 103, in that it may increase the existing degree of dishing 108. Moreover, the additional rework process step may increase the defect level due to the continuous exposure of surface areas to the influence of the abrasive particles and the chemicals contained in the slurry. In view of this situation, the process times for reworking are conventionally kept as short as possible so as to remove the residues 109 while trying to prevent or limit further damage in the remaining areas of the substrate.

Consequently, minor variations in any of the processes preceding the rework process step or during the rework process step itself may have a significant impact on the final result of the material removal process. For instance, any increased non-uniformity of the plating process for forming the copper layer 107 or of the subsequent CMP process for removing the bulk material of the copper layer 107 may leave behind more conductive residues 109 and, thus, put a greater burden onto the subsequent rework process. Moreover, due to the shortness of the rework process step, the controlling of this process is extremely difficult since, for example, an end point detection may not be reliable due to the weak signal change created by the residues 109. Thus, any variations of the start conditions of the rework process, i.e., size and number of the residues 109, may not efficiently be taken into account as the process time may not adequately be adapted to these variations.

In view of the problems described above, it would be highly desirable to have a CMP process allowing a higher degree of controllability in removing residues, such as copper and barrier metals, from a substrate surface.

### SUMMARY OF THE INVENTION

Generally, the present invention is based on the finding that lowering the removal rate at a final rework process step in a CMP process sequence may be accomplished by significantly lowering a down force, i.e., the pressure applied to the substrate during the polishing process, and/or by significantly increasing the relative speed between the substrate and the polishing pad. In this way, additionally, a selectivity of the removal rates for areas with the copper and barrier metal already sufficiently cleared and in areas having residues is achieved and these residues may be efficiently removed, while metal trenches and vias in other portions are not unduly affected and are maintained substantially intact.

According to one illustrative embodiment of the present invention, a method of planarizing a metal-containing workpiece surface comprises chemically mechanically polishing the surface with a first speed relative to a polishing pad and a first pressure applied to the workpiece to remove material from the surface. Moreover, the surface is chemically mechanically polished with a second relative speed higher than the first relative speed and a second pressure that is less than the first pressure and is in the range of approximately 5 kPa to 1 kPa.

According to another illustrative embodiment of the present invention, a method of planarizing a metal-containing workpiece surface comprises chemically mechanically polishing the surface with a first speed relative to a polishing pad and a first pressure applied to the workpiece to remove material from the surface. Moreover, the surface is chemically mechanically polished with a second relative speed higher than the first relative speed and a second pressure that is less than the first pressure wherein the second speed is approximately 180 meters per minute or more.

According to still a further illustrative embodiment of the present invention, a method of removing excess metal from a copper metallization layer including metal areas and dielectric areas comprises two steps. In a first step, the substrate is chemically mechanically polished to remove excess metal with a first removal rate until a main portion of the dielectric areas is cleared. In a second step, the substrate is chemically mechanically polished while controlling at least one of a relative speed and a pressure applied to the substrate to obtain a second removal rate less than the first removal rate to substantially completely clear the dielectric areas, wherein a polish time with the second removal rate is longer than approximately 5 seconds.

### BRIEF DESCRIPTION OF THE DRAWINGS

The invention may be understood by reference to the following description taken in conjunction with the accompanying drawings, in which like reference numerals identify like elements, and in which:

FIGS. 1a-1b schematically show cross-sectional views of a semiconductor structure including a patterned dielectric layer with metal trenches and vias formed therein;

FIG. 2 schematically depicts a CMP station;

FIGS. 3a-3c schematically depict three different situations during chemically mechanically polishing a substrate in a microscopic view; and

FIGS. 4a-4b schematically show a three-dimensional view of measurement results prior to and after a CMP process in accordance with one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

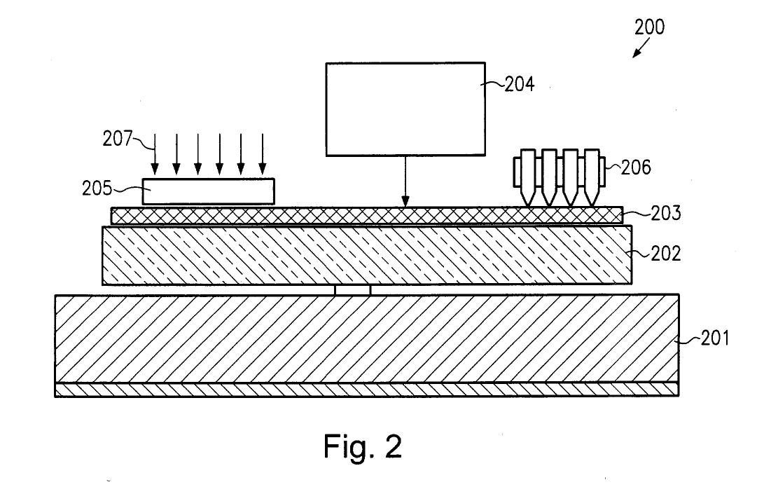

FIG. 2 schematically shows a cross-sectional side view of a CMP apparatus 200 in a simplified manner. In FIG. 2, the apparatus 200 comprises a base 201 with a polish platen 202 rotatively mounted thereon. A polishing pad 203 is attached to the platen 202 and is comprised of a suitable material for polishing a workpiece or a substrate 205 in combination with a slurry 204 supplied to the polishing pad 203. Moreover, a pad conditioner 206 is provided and adapted to rework the polishing pad 203 so that similar surface conditions may be established for a relatively large number of substrates. For convenience, any means for rotating the platen 202 and holding, conveying and pressurizing the substrate 205 and moving the pad conditioner 206 are not shown in FIG. 2.

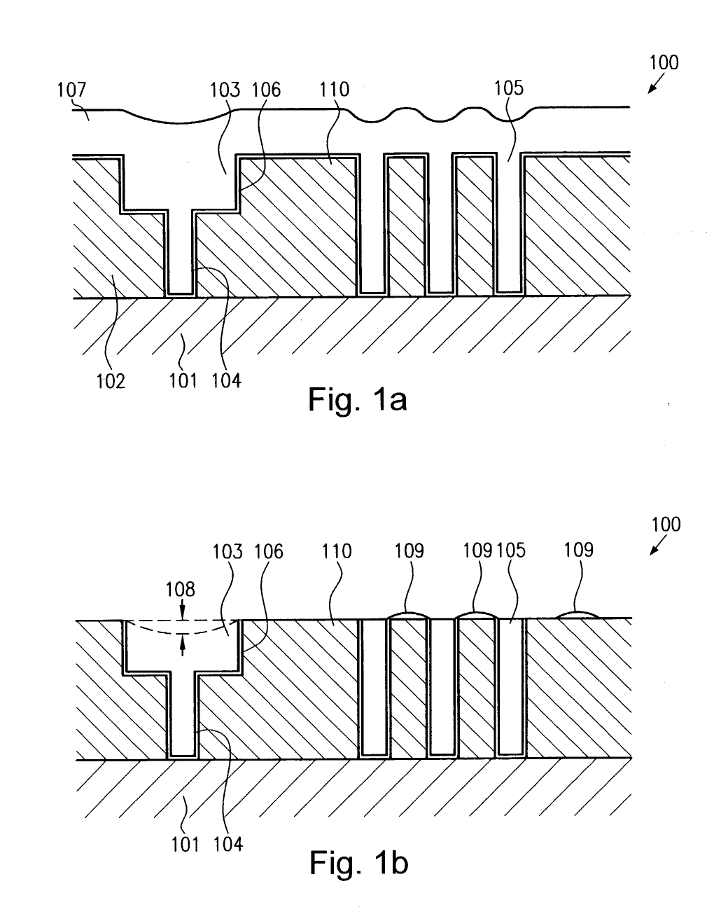

In operation, the substrate 205, including, for example, a semiconductor structure 100 as described with reference to FIG. 1a, is placed on the polishing pad 203 and an appropriate pressure is applied to the substrate, as indicated by 207, and a relative motion is established between the substrate 205 and the polishing pad 203. As previously noted, the removal rate of the material formed on the substrate 205, such as the excess copper 107, depends mainly on the type of slurry used, including a viscosity, and the type of abrasive particles in the slurry, the type of polishing pad, the pressure applied to the substrate 205 and the relative speed between the substrate 205 and the polishing pad 203.

In a typical process flow for removing excess copper, such as a copper layer 107 formed over the dielectric layer 102 to obtain conductive vias and lines, two or more polishing steps may be carried out, in which the pressure 207 is typically adjusted in a range of approximately 15-60 kPa for a slurry including silica particles having a size in the range of a few nanometers wherein a viscosity is in the range of approximately 1-20 cPs. The relative speed is adjusted in a range of approximately 20-180 meters per minute. These parameter values are required for achieving the desired removal rate of approximately 200-800 nanometers per minute. After this chemical mechanical polishing, possibly including several separate polishing steps and eventually to be carried out on different platens 202 as sophisticated CMP tools 200 may include a plurality of substantially identical polish stations, the bulk copper may be removed such that the semiconductor structure 100 is obtained as shown in FIG. 1b.

Subsequently, and contrary to a conventional process flow, one or more process parameters, such as the relative speed and/or the pressure 207, are altered so as to significantly lower the removal rate to a degree that still allows material removal that, however, prolongs the process time so that the conductive residues 109 may be reliably removed within a time scale that is conveniently controllable. This process period, which will also be referred to as reworking of the substrate 205, may immediately be performed after completion of removal of the bulk copper on the same polishing pad 203, or, in other embodiments, may be carried out on a separate polish station having a similar structure as shown in FIG. 2. Irrespective of whether the rework process is carried out on the same or on a different CMP station, a rinse step may be inserted to remove slurry residues in case a different slurry composition is to be used in the rework process step.

In other embodiments, one or more of the process parameters being altered may gradually be varied to continuously transit from the step of removing the bulk material to the rework process, or the transition may be carried out in a step-like manner until the final setting for the rework process is reached.

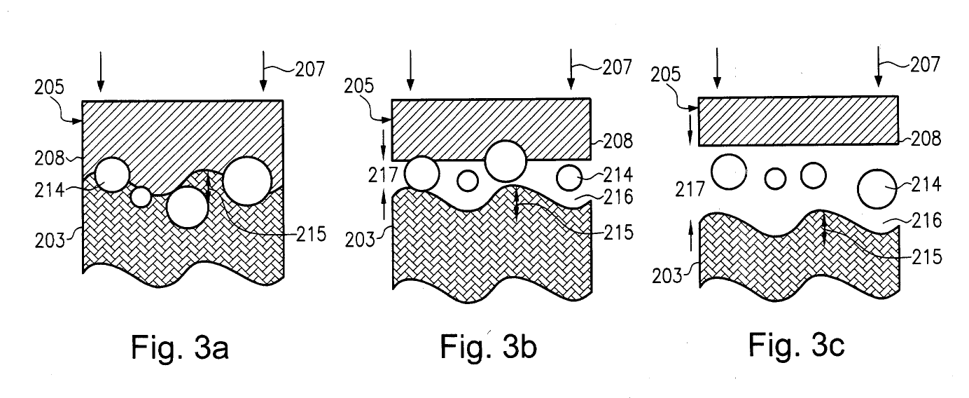

In one particular embodiment, the relative speed is increased to a value of approximately 180 meters per minute and more, and/or the pressure is lowered to approximately 5 kPa or less. In other embodiments the relative speed is selected to a value of approximately 200 meters per minute and more, and/or the pressure is lowered to approximately 3 kPa or less, thereby increasing the layer of slurry formed between the polishing pad 203 and the substrate 205, as will be described in more detail with reference to FIGS. 3a-3c.

FIG. 3a shows a cross-sectional view of a portion of the polishing pad 203 and the substrate 205, wherein a surface region 208 is substantially in contact with the polishing pad 203 exhibiting an averaged surface roughness, as indicated by 215, whereby abrasive particles 214 contained in the slurry 204 are present in the surface region 208 and the polishing pad 203. Due to the relative motion between the substrate 205 and the polishing pad 203, material is removed from the surface region 208 caused by the interaction of the particles 214 with the material to be removed, such as the copper 107. The removal rate depends on the pressure 207, the type of particles 214, the type of polishing pad 203 and the magnitude of the relative speed between the substrate 205 and the polishing pad 203. It is believed that a regime as shown in FIG. 3a is created by exerting a pressure of 15-60 kPa and by selecting the relative speed in the range of approximately 20-180 meters per minute for commonly used slurries. These parameters may be conveniently controlled during operation. Due to the direct contact between the substrate 205 and the polishing pad 203, a high removal rate is obtained. Such a process may be performed to remove the majority of the bulk copper layer 107.

FIG. 3b schematically shows the CMP regime with increased relative speed and/or lowered pressure 207 so that an average distance 217 between the polishing pad 203 and the surface region 208 increases as more liquid phase 216 of the slurry 204 accumulates there-between. In FIG. 3b, the distance 217 is on the order of the average surface roughness 215. Due to the reduced interaction between the polishing pad 203 and the surface region 208, the particles 214 are, to a certain degree, mobile and do not effectively mediate the interaction between the substrate 205 and the polishing pad 203. The removal rate is reduced compared to the situation as shown in FIG. 3a.

FIG. 3c schematically shows a situation that may be referred to as hydrodynamic lubrication, wherein the distance 217 is significantly greater than the average surface roughness 215. In this regime, any interaction transmitted by the particles 214 is extremely low and, thus, substantially no material is removed. This condition may be achieved by extremely lowering the pressure 207 to approximately 0.1 kPa and less and by correspondingly raising the relative speed to approximately 200 meters per minute or more.

The rework process is designed to significantly reduce the removal rate, while at the same time avoiding the “hydrodynamic lubrication” regime as shown in FIG. 3c. Operating the CMP apparatus 200 in a regime as represented by FIG. 3b, for example, in the above-identified parameter range of approximately 120 meters per minute and/or a pressure of 10-1 kPa, and, more preferably, with approximately 150 meters per minute or more and/or 7 kPa or less, it turns out that not only the removal rate is reduced to allow process times of approximately 5-80 seconds for sufficiently removing the conductive residues 109, but also, surprisingly, a high selectivity of removal of material in substrate portions that are already cleared and substrate portions including the residues 109 is obtained. Without limiting the present invention to the following explanation, it is believed that in the regime as exemplarily shown in FIG. 3b, the interaction of the particles 214 is preferably restricted to uneven surface regions 208 including the residues 109, whereas other portions exhibiting a relatively even surface, especially the surface of the trench 103, are only minimally affected by the ongoing CMP process. It should be noted that the above value ranges are suitable for slurries presently used for copper CMP with a viscosity in the range of approximately 1-20 cPs.

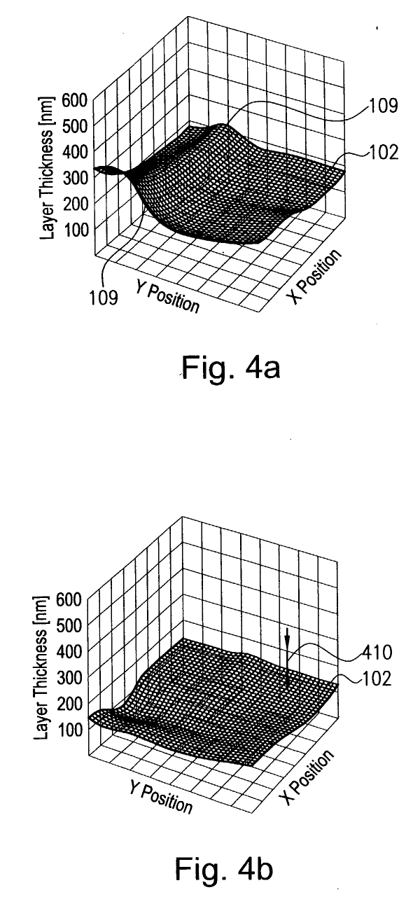

FIG 4a shows a three-dimensional plot of measurement results of a semiconductor structure, such as the structure 100 as shown in FIG. 1b, prior to the final rework CMP, wherein the structure, such as the structure 100 of FIG. 1b, includes copper residues 109 formed on the dielectric layer 102. As is evident from FIG. 1a, the initial layer thickness of the layer 102 is approximately 170 nm whereas the height of the residue 109 exceeds approximately 310 nm.

FIG 4b shows the measurement results after reworking the structure 100 with a relative speed of approximately 200 meters per minute and a pressure of approximately 3 kPa with a rework time of approximately 20 seconds and a slurry as specified above. As is apparent, the residues 109 are substantially completely removed, while the material removal of the dielectric layer 102 is in the range of 30-40 nm and is, thus, significantly less than the removal of the residues 109 having a height in the range of 140 nm and more. Moreover, due to the decreased removal rate compared to the regime shown in FIG. 3a and as used in the CMP period preceding the rework phase, the rework process according to the present invention is precisely controllable and reproducible, as any variation of the height of the residues 109 only negligibly affects the removal of the dielectric layer 102 and also of any metal as, for example, contained in the trench 103. For example, a variation of the height of the residues 109 of 20% would thus result in an additional removal of 6-8 nm of the dielectric layer 102, which is well within the process specification. Thus, a single rework process time may be selected that provides reliable remove of residues having a height within a specified variation range, wherein the specified variation range may be selected broad enough to account for variations of preceding process steps. Thus, the high selectivity of the rework process may allow relaxation of the restriction posed on a preceding process. In other embodiments, when a measurement precedes the final rework phase, the process time may be readily adapted in accordance with measurement results due to the relatively long process time of the rework period.

In other embodiments, the relative speed and/or the pressure applied to the substrate 305 may be varied to adjust the rework process to different residual heights. In a further embodiment, the pressure 307 applied to the substrate may be increased as the rework process continues in order to take into account the reduced height difference between even surface portions and the residues 109 so that the degree of interaction between the slurry particles 314 and the residue 109 (see FIG. 3b) is kept within a desired predefined range. Similarly, the relative speed may be lowered to also maintain a desired removal rate during the rework process. These embodiments are advantageous when a high tool throughput is desired while nevertheless a desired high safety margin in substantially completely removing the copper residues 109 is to be maintained.

In a further embodiment, an endpoint signal may be used to control the relative speed and/or the pressure. Sophisticated CMP tools may include an optical system (not shown in FIG. 2) that sends light to a portion of the workpiece surface to be polished and provides a signal indicative of the light reflected from the surface. For example, a decreasing signal of the reflected light may indicate an increasing degree of clearance of the surface due to the reduced reflectivity of the dielectric material compared to the copper. The process parameters may then be set, gradually or step-like, to the above-identified values depending on the endpoint signal. For example, upon detection of a predefined signal level, the rework process may be started, or a gradual transition from the current process state to the rework phase may be carried either in a predefined manner or controlled by the endpoint detection signal.

As a result, the present invention provides effective removal of metal residues, especially copper residues, after the bulk material is removed by chemical mechanical polishing. Process parameters, such as the relative speed and the pressure, are adjusted to operate the CMP apparatus in a regime that is well below the hydrodynamic lubrication regime while at the same time the removal rate is significantly lower than during the process phase for removing the bulk material. Thus, the process time for the rework phase may be remarkably increased to enhance the process controllability and reliability.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of planarizing a metal-containing workpiece surface, the method comprising:
chemically mechanically polishing the surface with a first speed relative to a polishing pad and a first pressure applied to the workpiece to remove material from said surface; and
chemically mechanically polishing the surface with a second relative speed higher than said first relative speed and a second pressure that is less than said first pressure and is in the range of approximately 5 kPa to 1 kPa.

2. The method of claim 1, wherein said second relative speed is higher than approximately 180 meters per minute.

3. The method of claim 1, wherein said metal comprises at least one of copper and a barrier metal.

4. The method of claim 3, wherein said chemical mechanical polishing with said second relative speed and said second pressure is carried out immediately after polishing said surface with said first relative speed and said first pressure.

5. The method of claim 1, further comprising a transition period between said chemical mechanical polishing with said first relative speed and said first pressure and said chemical mechanical polishing with said second relative speed and said second pressure.

6. The method of claim 5, wherein said transition period includes rinsing the workpiece.

7. The method of claim 5, wherein said transition period includes at least one of continuously and step-like varying at least one of a relative speed and a pressure.

8. The method of claim 1, wherein said second relative speed is higher than approximately 200 meters per minute.

9. The method of claim 1, wherein said second pressure is less than approximately 3 kPa.

10. The method of claim 1, wherein said second relative speed is higher than approximately 200 meters per minute and said second pressure is less than approximately 3 kPa.

11. The method of claim 1, further comprising obtaining an endpoint detection signal and starting said chemical mechanical polishing with said second relative speed and said second pressure on the basis of said endpoint detection signal.

12. A method of planarizing a metal-containing workpiece surface, the method comprising:
chemically mechanically polishing the surface with a first speed relative to a polishing pad and a first pressure applied to the workpiece to remove material from said surface; and
chemically mechanically polishing the surface with a second relative speed higher than said first relative speed and a second pressure that is less than said first pressure wherein said second speed is approximately 180 meters per minute or more.

13. The method of claim 12, wherein said second pressure is approximately 5 kPa or less.

14. The method of claim 12, wherein said metal comprises at least one of copper and a barrier metal.

15. The method of claim 12, wherein said chemical mechanical polishing with said second relative speed and said second pressure is carried out immediately after polishing said surface with said first relative speed and said first pressure.

16. The method of claim 12, further comprising a transition period between said chemical mechanical polishing with said first relative speed and said first pressure and said chemical mechanical polishing with said second relative speed and said second pressure.

17. The method of claim 16, wherein said transition period includes rinsing the workpiece.

18. The method of claim 16, wherein said transition period includes at least one of continuously and step-like varying at least one of a relative speed and a pressure.

19. The method of claim 12, wherein said second relative speed is higher than approximately 200 meters per minute.

20. The method of claim 12, wherein said second pressure is less than approximately 3 kPa.

21. The method of claim 12, wherein said second relative speed is higher than approximately 200 meters per minute and said second pressure is less than approximately 3 kPa.

22. The method of claim 12, further comprising obtaining an endpoint detection signal and starting said chemical mechanical polishing with said second relative speed and said second pressure on the basis of said endpoint detection signal.

23. A method of removing excess metal from a copper metallization layer including metal areas and dielectric areas, the method comprising:
a) chemically mechanically polishing the substrate to remove excess metal with a first removal rate until a main portion of said dielectric areas is cleared; and
b) chemically mechanically polishing the substrate while controlling at least one of a relative speed and a pressure applied to the substrate to obtain a second removal rate less than said first removal rate to substantially completely clear said dielectric areas, wherein a polish time with said second removal rate is longer than approximately 5 seconds.

24. The method of claim 23, wherein a slurry solution used in a final phase of step a) and a slurry solution used in step b) have a substantially identical viscosity.

25. The method of claim 23, wherein said pressure is approximately 5 kPa or less.

26. The method of claim 23, wherein said relative speed is higher than approximately 200 meters per minute.

27. The method of claim 23, wherein said pressure is less than approximately 3 kPa.

28. The method of claim 23, wherein said relative speed is higher than approximately 180 meters per minute.

29. The method of claim 23, wherein said relative speed is higher than approximately 200 meters per minute and said pressure is less than approximately 3 kPa.

30. The method of claim 23, further comprising obtaining an endpoint detection signal and starting said chemical mechanical polishing with said second removal rate on the basis of said endpoint detection signal.
